(19) United States
(12) Patent Application Publication
(10) Pub. No.: US 2016/0223601 A1
(43) Pub. Date: Aug. 4, 2016

(54) ENERGY MONITORING METHOD AND APPARATUS

(71) Applicant: EMBERTEC PTY LTD, Dulwich, South Australia (AU)

(72) Inventor: Domenico Gelonese, Dulwich, South Australia (AU)

(21) Appl. No.: 15/022,258

(22) PCT Filed: Sep. 19, 2014
(86) PCT No.: PCT/AU2014/000918

§ 371 Date: Mar. 16, 2016

(30) Foreign Application Priority Data
Sep. 19, 2013 (AU) 2013903608

(51) Int. Cl. G01R 22/06

(52) U.S. Cl. CPC G01R 22/063

(57) ABSTRACT

An In Home Display (IHD) device adapted to display electricity usage of a household in data communication with a Smartmeter and in data communication with an intelligent power manager. The IHD provides a channel for the transmission of household descriptive data to the intelligent power manager. The intelligent power manager communicates with a number of IHDs each associated with a respective household. The intelligent power manager will process and compare data from the IHDs prompting a householder to take actions based on said comparison.

### TECHNICAL FIELD

The present invention relates to the field of energy demand monitoring and management.

### BACKGROUND ART

The following references to and descriptions of prior proposals or products are not intended to be and are not to be construed as statements or admissions of common general knowledge in the art. In particular, the following prior art discussion does not relate to what is commonly or well known by the person skilled in the art, but may assist in the understanding of the inventive step of the present invention, of which the identification of pertinent prior proposals is but one part.

In Home Displays (IHD) are devices which, at their most basic, display to a householder the amount of electrical energy being consumed by the household at an instant in time. IHDs are becoming more common in homes as a way to illustrate to householders what energy they are using at a particular point in time.

The expectation has been that householders will use this information to change behaviour and appliance use habits in order to save energy and hence money.

However, it is a significant challenge for the householder to determine which devices are using the energy and then to use the information to change use habits to save energy.

Those with knowledge of the field believe that sustained behavioural change is not likely and thus the initial energy efficient actions of householders will at some stage revert back to previous habits.

This may be in part because of the difficulty of making changes to habits without any motivation beyond monetary savings which are spread over a long period.

There currently exist a number of companies who provide services where a given householder's energy consumption can be compared to the average of the same area in their monthly or quarterly energy rates notices. These notices then provide helpful hints on how to lower energy usage. This is an attempt to motivate the householder by using the natural human desire to conform to or exceed the performance of their peers. However, the helpful hints are usually commonly known and do not provide a detailed analysis specific to the household as to what the energy efficiency advantage would be. Further, the monthly or quarterly nature of the comparison is not sufficiently frequent to generate any feeling of competitiveness. The significant differences between the households in an area also contributes to a perception that the comparison with local averages can be ignored as invalid because the householder perceives their household to be different from that of the immediate neighbours.

### DISCLOSURE OF THE INVENTION

Householders may however be more interested in what energy efficient products they could utilise to lower their energy consumption without a change in their user habits and therefore deliver sustained, long term energy efficiency through the use of more energy efficient products/technologies.

The challenge for the householder is deciding what products/technologies they should adopt given the many options available to them.

In one form of this invention although this may not necessarily be the only or indeed the broadest form of this there is proposed a computer implemented system for reducing household energy use including first measurement means adapted to measure the aggregate energy usage of a household;

second measuring means adapted to measure the energy usage of an individual appliance or group of appliances within the household;
user interface means adapted to provide a user interface for a householder to interact with the system;
a hub including first communication means adapted to communicate with the first and second measurement means and the display means;
the system including an intelligent power manager adapted to communicate with a plurality of said hubs each associated with a respective household, and to receive data describing the energy use of the respective households as measured by the first and second measurement means of each hub, the power manager further adapted to process and compare data from the plurality of hubs and to effect reduction in energy usage of the household by prompting a householder to take actions based on said comparison.

In an embodiment the data describing the energy use of the respective households is data collected in the previous one hour time period.

In preference the data describing the energy use of the respective households is data collected in the previous twenty-four hour time period.

In an alternative embodiment the data describing the energy use of the respective households is data collected in the previous seven day time period.

In preference the intelligent power manager further receives from the plurality of hubs household descriptive data describing the type of electrical appliances, the number and habits of the members of the household, and physical characteristics of the dwelling of the household;

the intelligent power manager using the household descriptive data to identify similar households and to provide prompting to the householder based on comparisons with the identified similar households.

The household descriptive data may be one or more of dwelling size, occupant profile, presence and type of air conditioning system, presence and type of hot water system, presence and type of swimming pool equipment, type of cooking appliance, and type of lighting system.

In preference at least a part of the household descriptive data is deduced from analysis of the aggregate household energy use data and/or the appliance energy use data.

The user interface may provided by a computing device remote from the hub which is in data communication with the intelligent power manager. An example of such a device would be a tablet computer. A further example would be a smartphone.

In preference the householder is prompted to change energy use behaviour, for example by setting a higher or lower set point temperature on an air-conditioning thermostat.

In preference the householder is prompted to install appliance management means, such a home automation equipment able to switch on and off appliances to a schedule which uses less electricity.

In preference the householder is prompted to replace inefficient appliances, such as older refrigerators, televisions and air-conditioning units which are very much less energy efficient than more modern devices of the same type.

In a further form, the invention may be said to lie in a hub for reducing energy use in a household which can receive data describing the aggregate energy use of the household and receive data describing the energy usage of one or more electrical appliances within the household the hub then being able to communicate the received data to an intelligent power manager adapted to receive and compare such data from a number of similar hubs installed in other households.

The hub may use the data describing the appliance energy use, and the data describing the aggregate energy use to deduce household descriptive data which describes characteristics of the household, its energy use and its makeup, and to communicate said household descriptive data to the intelligent power manager.

The hub may be further adapted to receive via a user interface, household descriptive data and to communicate said household descriptive data to the intelligent power manager.

The user interface may integral to the hub or may be provided by a computing device remote from the hub which is in data communication with the hub.

### BRIEF DESCRIPTION OF THE DRAWINGS

FIG. 1 is a diagrammatic representation of a household including the system of the invention.

FIG. 2 is a diagrammatic representation of a household including the system of the invention where a communications hub is not provided.

### BEST MODE FOR CARRYING OUT THE INVENTION

In the consumer premises 110 which is a household dwelling, there is provided a user interface device called an In Home Display (IHD) 102. The IHD is able to display information and analysis results to a user. The IHD may be provided in a number of ways. In a preferred embodiment, the IHD is provided as a software service running on a general purpose tablet device, for example an iPad, or a smartphone.

There is also provided a hub 100. The hub includes a communication transceiver which allows the hub to communicate with corresponding transceivers in electrical appliances 103 in the consumer premises. In the illustrated embodiment, the communication is via Zigbee links 106. Other communications links may be used, including other wireless protocols such as wi-fi. Alternative communication means such as wired Ethernet or powerline signalling systems may be used. A combination of communication links may be used, such that the hub has multiple communication transceivers.

In an alternative embodiment, the hub includes a display, and the IHD is provided as an integral part of the hub. In a further embodiment, the IHD is provided as software running on a general purpose computer, which may be either a desktop or a laptop computer.

Data communication between the hub and the IHD may be provided by wireless communication using any convenient protocol, for example, Zigbee or wi-fi. Communication may also be by direct wiring, or by a wired communication protocol such as ethernet.

The hub 100 is in data communication with a device which is able to measure the electricity consumption of the household in real time or with a high degree of granularity. In a preferred embodiment, this device is a Smartmeter 101. The Smartmeter is a device which measures the electricity consumption of the household for billing purposes. The Smartmeter is able to communicate this metering data to the household's energy retailer for billing purposes, but may also communicate the data to the hub.

In an embodiment, at least one of the appliances 103 is associated with an Appliance Communications Module (ACM) 107 which includes a transceiver able to communicate with the hub 100. The ACM is able to determine, and to communicate to the hub, the current power usage of the associated appliance.

In an alternative embodiment, usage data for individual appliances 104 which are not able to communicate directly with the hub may be determined by analysis of the electricity usage data from the Smartmeter. The usage of particular appliances may be identified by the characteristic signature of the electricity consumption caused by that use. The ACM is not essential, nor is the automatic identification of individual appliances and the usage patterns of those appliances. Improved information can be provided to the householder where this information is available.

The hub is also in data communication with a remote Intelligent Power Manager (IPM) 108. In a preferred embodiment, this communication is via a generic broadband internet connection 109, provided by the household. In other embodiments, communication may be by any convenient method, including without limitation, a Zigbee network, a mobile data network, and a dial-up internet connection.

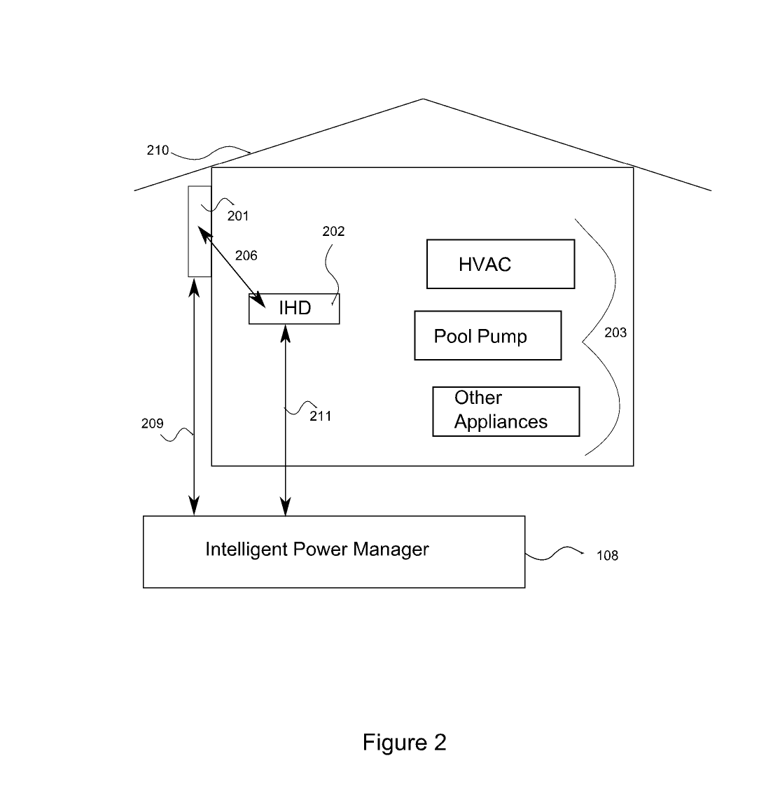

FIG. 2 shows an alternative embodiment of the energy saving system where a separate hub is not provided.

In the consumer premises 210, there is provided an In Home Display (IHD) 202. The IHD is able to display information and analysis results to a user. The IHD may be provided in a number of ways. In a preferred embodiment, the IHD is provided as a software service running on a general purpose tablet device, for example an iPad, or a smartphone.

In a further embodiment, the IHD is provided as software running on a general purpose computer, which may be either a desktop or a laptop computer.

The household requires electrical energy to power appliances 203, such as Heating and Ventilation and Air Conditioning (HVAC) equipment, a swimming pool pump and other appliances.

The IHD 202 is in data communication with a Smartmeter 201. The Smartmeter is a device which measures the electricity consumption of the household for billing purposes. The Smartmeter is able to communicate this metering data to the household's energy retailer for billing purposes and communicate electricity usage data to the IHD for display to the householder.

In an alternative embodiment, usage data for individual appliances 103 may be determined by analysis of the electricity usage data from the Smartmeter. The usage of particular appliances may be identified by the characteristic signature of the electricity consumption caused by that use.

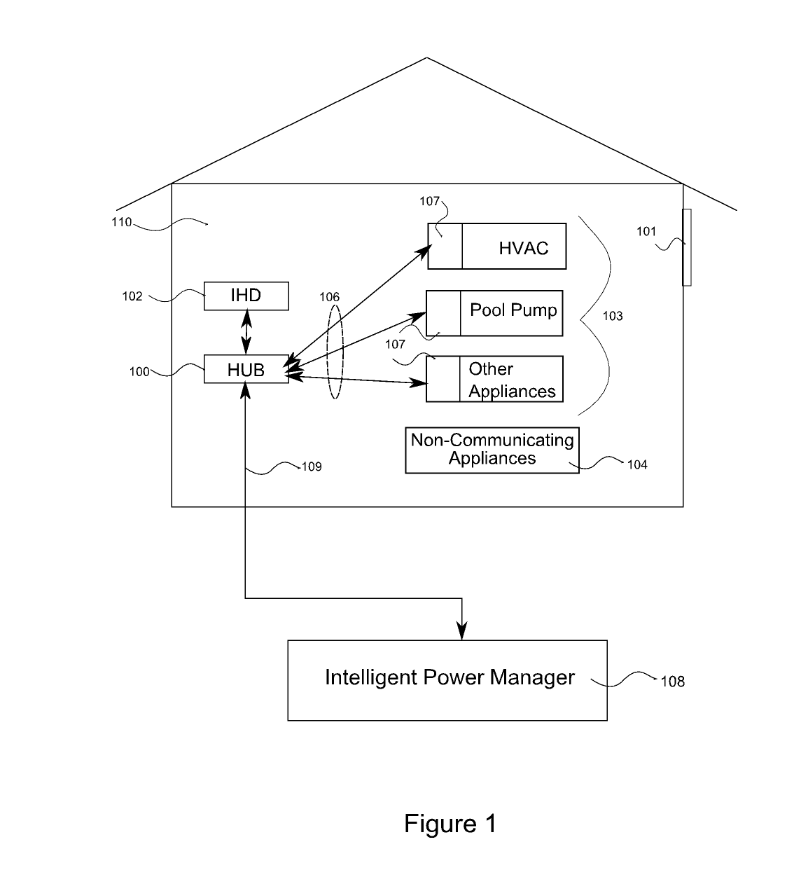

The IHD is also in data communication 206 with a remote Intelligent Power Manager (IPM) 108. This is the same IPM as described for the embodiment of FIG. 1. In a preferred embodiment, this communication is via a generic broadband internet connection 211, provided by the household. In other embodiments, communication may be by any convenient method, including without limitation, a Zigbee network, a mobile data network, and a dial-up internet connection.

The Smartmeter may be in data communication 209 directly with the IPM. This is particularly preferred in the case where the IPM is provided or hosted by the energy retailer.

The IPM is a remote computer processor which is in communication with multiple hubs situated at multiple households. The IPM is able to record and analyse data on electricity consumption and where available, individual appliance electricity consumption, from multiple households, in preference, a large number of households.

The IPM also records, where available, information regarding the make-up of the households, the appliances in each household, and the geographic location of each household.

The IPM monitors and tracks the energy usage patterns of a particular household and compares this data to similar sized homes preferably in real time, or at intervals significantly less than the household electricity billing interval, to provide the basis for householders to compare their energy usage with that of others during particular time periods.

Data from the household on energy usage and the other data concerning household make-up which is of use to compare homes and better profile their energy usage is encrypted and stored in the IPM.

The householder can then access their energy usage information from the IPM at any time to assess their energy usage over certain time periods, i.e. over the last hour, 24 hours, week, month, etc.

This information can be accessed via the hub and displayed via the IHD. Alternatively, the information can be accessed directly from the IPM by a computer or computing device which is in direct data communication with the IPM via, for example, the public internet, where the computer and the IPM provide a full user interface.

Via the hub, the IHD, or such a user interface, the householder can enter household description data, which describes the makeup of the household, details of the dwelling, and information about the appliances in use in the household. The greater detail the householder is willing to provide, the more accurate comparisons may be mad against other households.

The householder can then choose to compare their energy usage to other households over any selected time period. The households against which the comparison is made may be selected by any combination of energy usage characteristics, household characteristics or geographic characteristics.

Without limitation, these may include
Size and configuration of dwelling
Household makeup
Presence and type of air-conditioning system
Type of Hot Water system
Presence and type of swimming pool equipment
Type of heating system
Type of cooking system
Type of lighting system
Physical location

This then allows the householder to compare their energy usage against similar households to see how they compare in a like for like scenario.

Selection of similar households may be made directly by the householder, or the IPM may select one or a group of households as the comparison target based on the household description data.

The IPM compares the energy usage of the households selected by the householder or by the IPM as being similar according to these criteria with the energy usage of the target household. The differences are displayed to the householder. The householder is shown in what way their household differs from similar households with different energy consumption in terms of the differences in the technology utilised in other households in order to highlight reasons as to why their energy consumption is different. This will then allow the householder to evaluate energy efficient products and technologies which may be of value to them.

Similarly the IPM will undertake this analysis for individual householders to provide them with regular (or as requested by the householder) detailed analysis of their energy usage compared to similar homes. The IPM can provide recommended energy efficiency options for the householder which are in use in similar households. Where a similar household has adopted an energy efficiency measure, the energy usage before and after such an adoption is known to the IPM. The IPM can then predict the result of adoption of that same measure by a target household, taking into account the effect of any small differences between the adopting household and the target household. Links to or information about providers of the recommended technology can be provided to the IHD for display to the householder.

The IPM analyses and compares households. This data is presented to householders for their information, and to allow them to make choices about behavioural changes which will save energy. The results of such changes can be simulated, based on households which have been selected as similar where such behaviours are undertaken.

It is known that behavioural change, while effective and cheap, is difficult to maintain. Accordingly, the IPM is also able to provide recommendations for solutions which may be higher cost, but which do not require the effort of changing household habits.

The IPM may recommend retrofit appliance control solutions which automate the recommended changes in appliance control. This allows the householder to benefit from the energy savings of such control changes without the need to change habits.

Where the IPM is able to identify particular appliances, these may be identified as being inefficient compared to other appliances which would perform the same function. For example, an older, inefficient refrigerator may be identified. The IPM is able to recommend replacement appliances with superior energy efficiency. The IHD may display links to information about such appliances and information from providers of such appliances. In an embodiment, replacement appliances can be ordered via the IHD, and installation arranged.

The IPM provides the householder with a choice of a range of solutions. These may include less expensive options which involve only changes to energy use habits. Basic home automation such as the use of programmable power switches may be suggested. At the most expensive the replacement of older, less energy efficient appliances with new, efficient appliances may be suggested.

The IPM provides an ongoing energy audit function which detects energy inefficiencies in the household and provides recommendations for solutions.

The IPM can provide the householder with validated information concerning energy efficiency solution payback periods.

The IPM has access to data over a large number of households, allowing simulations of the power savings from installation of control measures or of new appliances to be made with considerable accuracy, by comparing the performance of those measures or appliances in similar households. This allows payback periods to be calculated with accuracy.

One method for reducing electricity bills by reducing energy supplied by an energy retailer is the installation of solar or wind electricity generation capacity, with or without accompanying energy storage capacity such as batteries. The cost of such installations is relatively high, and is affected by many variables. It is difficult to predict the payback of such generation capacity installations and to calculate whether an installation of a particular type or size is economically advantageous. Where the electricity utility provides energy under a time of day tariff, but also pays a feed-in tariff for some or all energy generated by the household generation capacity, then household habits and energy usage patterns must be factored in. The hub receives electricity generation data from the generation installation. The IPM is thus able to make recommendations and predictions about the performance of any contemplated generation installation, based on real world experience of comparable households.

The hub may also contribute to allowing the household to participate in demand response (DR) events. Such events occur when an electricity supply utility has a requirement to reduce electricity demand for a relatively short period. This requirement is communicated in various ways, but in general some rebate, payment or other benefit is available to energy users who are able to make the requested reduction in energy consumption.

The hub is able to monitor household loads to locate large loads in the home including without restriction, air-conditioning installations and swimming pool pumps that are operated during periods where DR control would be valuable. Finding these homes and selectively marketing to them automated control solutions so that they can receive financial or other incentives from participation in future DR events is of value for the householder. An advantage is also available to the energy supply utility. The utility can locate and target customers and customer groups for marketing DR solutions instead of simply providing a blanket DR effort across all customers where some will yield demand reduction benefits and others will not.

In an embodiment the ACM for a particular appliance may be integrated into the appliance at manufacture. The hub may include protocols necessary to communicate with the integrated ACM, or the hub may be able to be programmed in the field, including by the ACM, to include the necessary communications protocols.

In a yet further embodiment, the hub may be provided as a web site provided by the IPM, which may be accessed by a user using a general purpose web browser. In this case the appliances may be provided with means to individually access the internet in order to communicate with the hub. The Smartmeter data may be provided directly to the hub or IPM by an energy retailer or distributor, being the owner or controller of the Smartmeter data. In an embodiment, the web site may be hosted by an energy retailer or distributor.

The invention has been described in terms of a residential entity, described as a household. However, the invention may be equally applied to commercial or factory entities, or any other discretely measureable, multi-load installation. The term “household” as used herein is intended also to cover such entities and installations.

Although the invention has been herein shown and described in what is conceived to be the most practical and preferred embodiment, it is recognised that departures can be made within the scope of the invention, which is not to be limited to the details described herein but is to be accorded the full scope of the appended claims so as to embrace any and all equivalent devices and apparatus.

1-18. (canceled)

19. A system for reducing household energy use including:
a. a hub configured to receive:
(1) household measurements representing the aggregate energy usage of the household, and
(2) appliance measurements representing the energy usage of individual appliances and/or groups of appliances within the household;
b. an intelligent power manager configured to receive household measurements and appliance measurements from the hub and from other hubs, each other hub being associated with a respective other household;
c. a user interface:
(1) in communication with the intelligent power manager, and
(2) configured to provide user-perceivable data representing the household measurements and appliance measurements of:
i. the household, and
ii. the other households.

20. The system of claim 19 further including a meter:
a. in communication with the hub, and
b. providing the household measurements representing the aggregate energy usage of the household.

21. The system of claim 19 wherein the user interface is provided by an In-Home Display remote from the hub.

22. The system of claim 19 wherein both the user interface and the hub are provided by an In-Home Display.

23. The system of claim 19 wherein the user interface is further configured to provide user-perceivable data representing suggestions for reduced energy consumption based on the household measurements and appliance measurements of:
a. the household, and
b. the other households.

24. The system of claim 19 wherein the user interface is further configured to identify individual appliances and/or groups of appliances within the household having appliance measurements which exceed the appliance measurements of at least some of the other households.

25. The system of claim 19 wherein the user-perceivable data provided by the user interface represents the household measurements and appliance measurements of the household and the other households over one or more of:
a. the preceding one hour time period;
b. the preceding twenty-four hour time period; and
c. the preceding seven day time period.

26. The system of claim 19 wherein:
a. the intelligent power manager further receives from the other hubs household descriptive data representing:
(1) the physical characteristics of the other households,
(2) the types of electrical appliances of the other households, and
(3) the occupants of the other households,
b. the user interface is further configured to provide the user-perceivable data for a subset of the other households which have household descriptive data most similar to that of the household.

27. The system of claim 26 wherein the user interface is further configured to provide user-perceivable data indicating that:
a. the household measurements, and/or
b. the appliance measurements of certain individual appliances and/or groups of appliances,
exceed the measurements of the subset of the other households.

28. The system of claim 26 wherein the user interface is further configured to provide user-perceivable data representing suggestions for reduced energy consumption based on the household measurements and appliance measurements of the subset of the other households.

29. The system of claim 26 wherein the household descriptive data includes one or more of:
a. dwelling size,
b. type of hot water system,
c. type of cooking appliances,
d. types of lighting systems,
e. presence and type of air conditioning system,
f. presence and type of swimming pool equipment,
g. number of occupants, and
c. age of occupants.

30. The system of claim 26 wherein at least a portion of the household descriptive data is estimated from analysis of the household measurements and appliance measurements of the other households.

31. The system of claim 19 wherein the hub is configured to receive the appliance measurements via one or more of:
a. wireless communications,
b. Ethernet communications, and/or
b. powerline communications,
with appliances.

32. A system for reducing household energy use including:
a. a meter configured to measure the household's energy usage;
b. an In-Home Display in communication with the meter;
c. an intelligent power manager configured to:
(1) receive from the In-Home Display household descriptive data characterizing one or more of
i. the physical characteristics of the household,
ii. the types of electrical appliances of the household, and
iii. the occupants of the other household,
(2) receive from In-Home Displays of other households:
i. measurements of the other households' energy usage, and
ii. other household descriptive data characterizing one or more of:
(a) the physical characteristics of the other households,
(b) the types of electrical appliances of the other households, and
(c) the occupants of the other households,
and wherein the In-Home Display provides user-perceivable data representing comparisons between:
A. the measurement of the household's energy usage and the measurements of the other households' energy usage, and
B. the household descriptive data and the other household descriptive data.

33. The system of claim 32 wherein the In-Home Display is further configured to provide user-perceivable data representing suggestions for reduced energy consumption based on the comparisons.

34. The system of claim 32 wherein the user interface is further configured to identify one or more appliances within the household having appliance measurements which exceed a threshold based on appliance measurements from the other households.

35. The system of claim 32 wherein the comparisons are made between:
a. the measurement of the household's energy usage, and
b. measurements of other households' energy usage from other households whose other household descriptive data is most similar to the household descriptive data.

36. The system of claim 32 wherein the household descriptive data includes one or more of:
a. dwelling size,
b. type of hot water system,
c. type of cooking appliances,
d. types of lighting systems,
e. presence and type of air conditioning system,
f. presence and type of swimming pool equipment,
g. number of occupants, and
c. age of occupants.

37. An In-Home Display for reducing household energy use, the In-Home Display being configured to:
a. receive measurements of the household's energy usage from a meter;
b. provide to an intelligent power manager household descriptive data characterizing one or more of:
(1) the physical characteristics of the household,
(2) the types of electrical appliances of the household, and
(3) the occupants of the other household,
c. receive from the intelligent power manager:
(1) measurements of other households' energy usage, and
(2) other household descriptive data characterizing one or more of:
i. the physical characteristics of the other households,
ii. the types of electrical appliances of the other households, and
iii. the occupants of the other households,
d. provide user-perceivable data representing comparisons between:
(1) the measurement of the household's energy usage and the measurements of the other households' energy usage, and
(2) the household descriptive data and the other household descriptive data.
